(19) United States
(12) Patent Application Publication
(10) Pub. No.: US 2002/0081811 A1
(43) Pub. Date: Jun. 27, 2002

(54) Low-temperature deposition of silicon nitride/oxide stack

(76) Inventors: Pietro Foglietti, Altdorf (DE); Berthold Staufer, Haug (DE); Josef Artinger, Dornwang (DE)

Correspondence Address: TEXAS INSTRUMENTS INCORPORATED, P O BOX 655474, M/S 3999, DALLAS, TX, 75265

(21) Appl. No.: 09/750,961

(22) Filed: Dec. 27, 2000

(51) Int. Cl. H01L 21/331; H01L 21/469; H01L 21/31

(52) U.S. Cl. 438/341; 438/763

(57) ABSTRACT

A method of fabricating an integrated circuit insulator stack, such as an emitter window dielectric, is disclosed. A single vacuum sequence (50) is performed in a low pressure chemical vapor deposition (LPCVD) process chamber. In one disclosed example, a layer of silicon dioxide (20) is first deposited by the chemical vapor deposition (44) of bistertiarybutylaminosilane (BTBAS) in the presence of oxygen; before removing the wafer from the process chamber, a layer of silicon nitride (22) is then deposited by the chemical vapor deposition (48) of BTBAS in ammonia. The CVD processes (44, 48) are performed at low pressures, such as 500 mTorr or less, and at low temperatures, such as below 650° C.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

This invention is in the field of integrated circuit manufacture, and is more specifically directed to the formation of insulating layers in bipolar transistors.

In the fabrication of modem integrated circuits, a layered stack of insulating films of different composition is often used to provide a high quality dielectric. One important example of such an insulator stack includes a silicon nitride (Si₃N₄) film and an overlying silicon dioxide (SiO₂) film. This nitride/oxide stack is often implemented as an emitter “window”, disposed between the base of a conventional double-diffused bipolar transistor and an overlying extrinsic emitter electrode. A hole is etched through this emitter window, prior to the formation of the emitter electrode, to provide a dopant diffusion path from the extrinsic emitter electrode into the base region. The diffused dopant forms the intrinsic emitter of the bipolar device.

FIGS. 1a and 1b illustrate, in cross-section and plan views, respectively, a conventional double-diffused bipolar n-p-n transistor. In this typical example, buried n+ collector region 4 is disposed at a surface of substrate 2, and underlies a more lightly-doped n-type intrinsic collector region 6. Intrinsic p-type base layer 8 is formed at the surface of collector region 6, as shown in FIG. 1a.

In this conventional device, an emitter “window” overlies a portion of base layer 8, and includes a stack consisting of silicon nitride layer 17 overlying silicon dioxide layer 15. Emitter polysilicon layer 12 is formed over oxide/nitride stack 15, 17, extending into opening W through oxide/nitride stack 15, 17 to contact base layer 8. Because emitter polysilicon layer 12 is relatively heavily doped n-type polysilicon, n-type dopant diffuses from emitter polysilicon 12 into base region 8 to form intrinsic emitter 10. As shown in FIG. 1b, this conventional bipolar transistor is typically formed as a rectangular structure, with opening W centrally located under emitter polysilicon layer 12 (as shown in shadow).

Other structures included in this conventional transistor include extrinsic base region 9, which is heavily doped p-type material formed into base layer 8 in a self-aligned manner, relative to sidewall insulator filaments 13 on the sides of emitter polysilicon 12 and oxide/nitride stack 15, 17. N+ collector sinker 14 provides a surface contact to buried collector layer 4. Electrical base, emitter, and collector contacts to extrinsic base 9, emitter polysilicon 12, and collector sinker 14 are made by way of metallization or other conductors (not shown), in the conventional manner.

The performance of modem integrated circuits including bipolar devices such as shown in FIGS. 1a and 1b is highly dependent on the doping concentration and distribution in the active region. In the n-p-n transistor example of FIGS. 1a and 1b, device performance is quite sensitive to the boron concentration and distribution width in the portion of base layer 8 underlying emitter 10. Unfortunately, however, these parameters are strongly influenced by high temperature manufacturing processes that are performed after the doping of this region. For example, because boron dopant is activated at 700° C., later processing at temperatures at or above 700° C. will cause movement of boron in base layer 8. Process control therefore dictates limits on the high temperature processing performed at later stages of the manufacturing process. Many device fabrication processes thus define a “thermal budget” of the time that the semiconductor wafers are at temperature in later manufacturing processes, to ensure desired performance.

The formation of oxide/nitride stack 15, 17 according to conventional processes consumes a significant part of the post-base thermal budget. A typical silicon nitride layer 17 of a thickness of 350 Å and silicon oxide layer 15 of a thickness of 1150 Å is conventionally performed by two separate low pressure chemical vapor deposition (LPCVD) processes. CVD of silicon oxide layer 15 is based on the decomposition of TEOS liquid at a temperature above 700° C., and CVD of silicon nitride layer 17 involves the decomposition of NH₃ and dichlorosilane (DCS) gases at a temperature above 700° C. Not only are the temperatures elevated above the activation temperature of boron, but because these processes are performed in separate vacuum process operations in separate process chambers, long process times at these temperatures are necessarily involved. For example, conventional LPCVD of silicon dioxide 15 and silicon nitride 17 as described above may take approximately 8.5 hours, with at least 4 of these hours at temperatures above 650° C. Further, as is known in the art, this conventional silicon nitride LPCVD chemistry necessitates frequent preventive maintenance to remove ammonium chloride residuals.

By way of further background, bistertiarybutylaminosilane (BTBAS) has been developed by the Schumacher unit of Air Products and Chemicals, Inc., as a liquid precursor for chemical vapor deposition (CVD). As described by its product literature, this precursor is useful in the deposition of silicon nitride, silicon dioxide, and silicon oxynitride, at temperatures in the range of from 550° to 650° C., and at pressures of 300 to 5000 mTorr, in conventional CVD or LPCVD reactors equipped for the liquid sources.

### BRIEF SUMMARY OF THE INVENTION

It is therefore an object of the present invention to provide a low temperature method of forming a stack of silicon nitride and silicon dioxide as the emitter window in a bipolar transistor.

It is a further object of the present invention to provide such a method in which the nitride/ oxide stack may be deposited in a single vacuum process.

It is a further object of the present invention to provide such a method that conserves the overall thermal budget of the manufacturing process.

Other objects and advantages of the present invention will be apparent to those of ordinary skill in the art having reference to the following specification together with its drawings.

The present invention may be implemented into a process for fabricating a bipolar transistor, for example in forming an insulator stack prior to the formation of emitter polysilicon. Silicon dioxide is deposited, by way of low pressure chemical vapor deposition (LPCVD) from the decomposition of bistertiarybutylaminosilane (BTBAS) in the presence of oxygen gas, preferably at a temperature below about 650° C. Upon the deposition of the desired thickness of silicon dioxide nitride, the oxygen gas source is turned off; LPCVD of silicon nitride is then performed, in the same vacuum cycle as the oxide deposition, by decomposing BTBAS in the presence of ammonia (NH₃). The LPCVD sequence may be carried out in a conventional vertical LPCVD reactor.

### BRIEF DESCRIPTION OF THE SEVERAL VIEWS OF THE DRAWING

FIGS. 1a and 1b are cross-sectional and plan views, respectively, of a conventional bipolar transistor.

FIGS. 2a through 2c are cross-sectional views of a bipolar transistor at various stages in its manufacture according to the preferred embodiment of the invention.

FIG. 3 is a flow chart illustrating a method of fabricating a transistor according to the preferred embodiment of the invention.

### DETAILED DESCRIPTION OF THE INVENTION

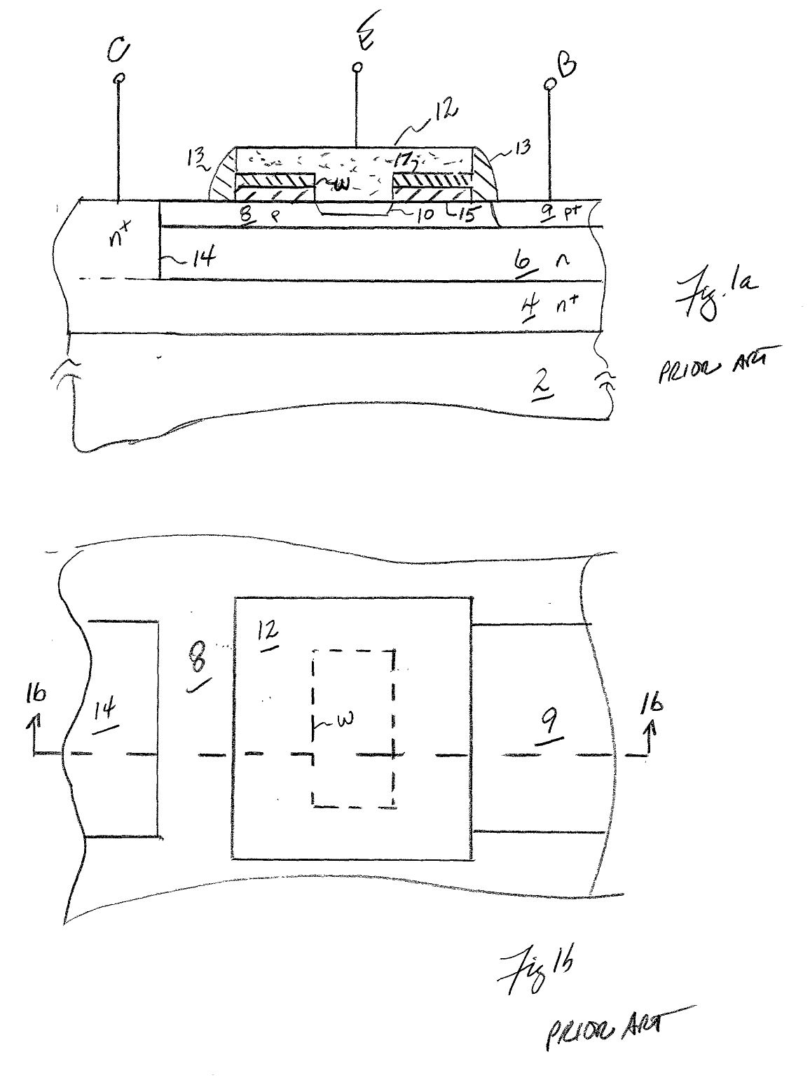

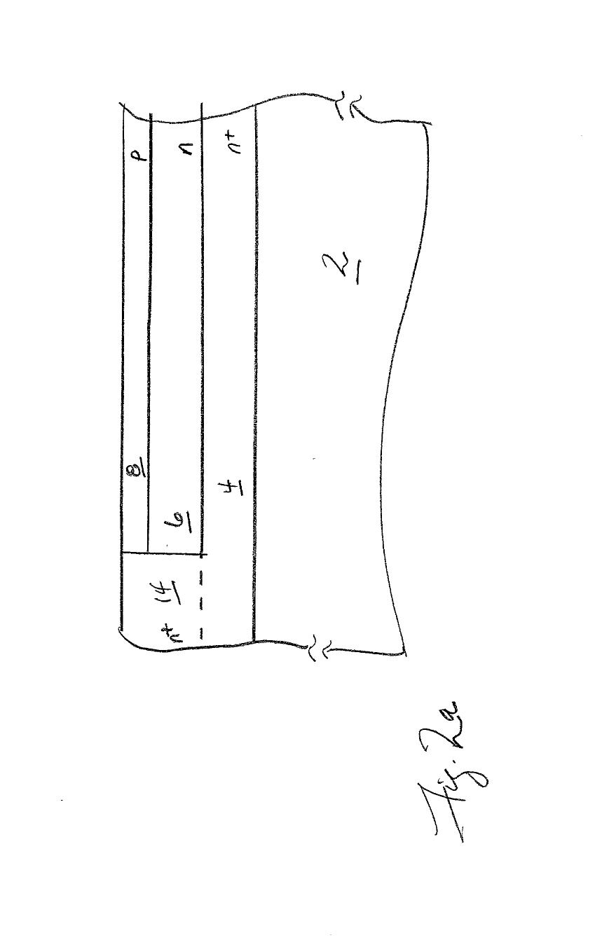

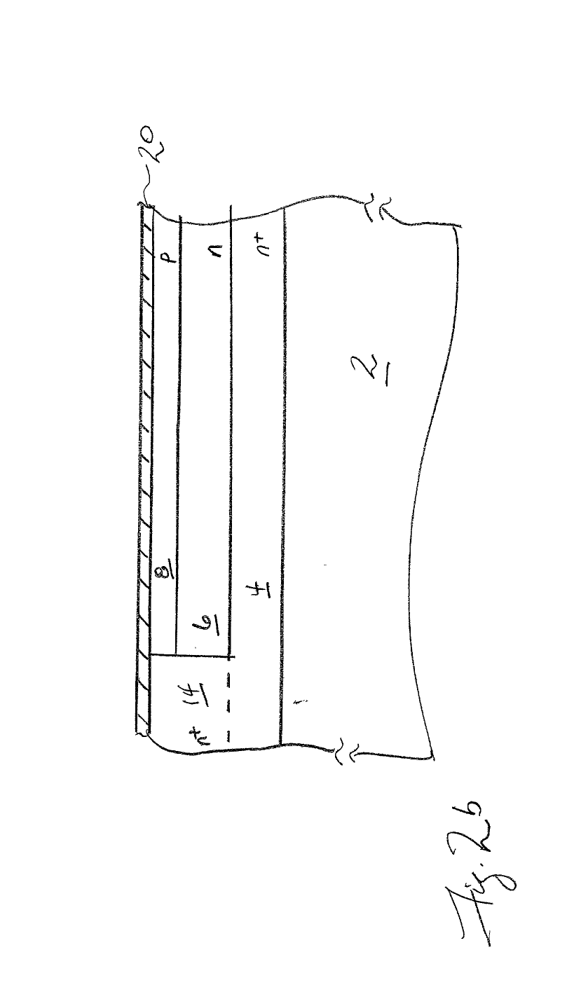

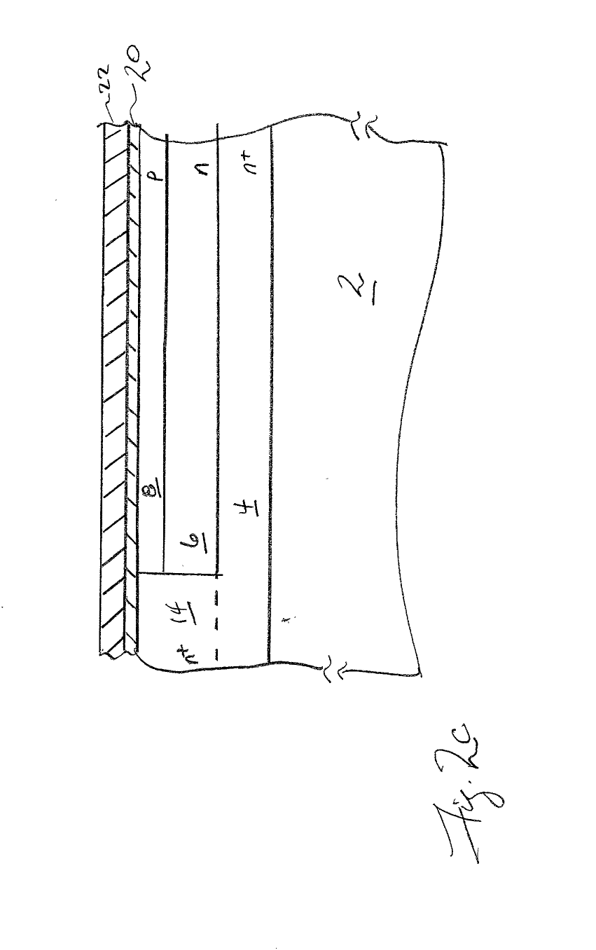

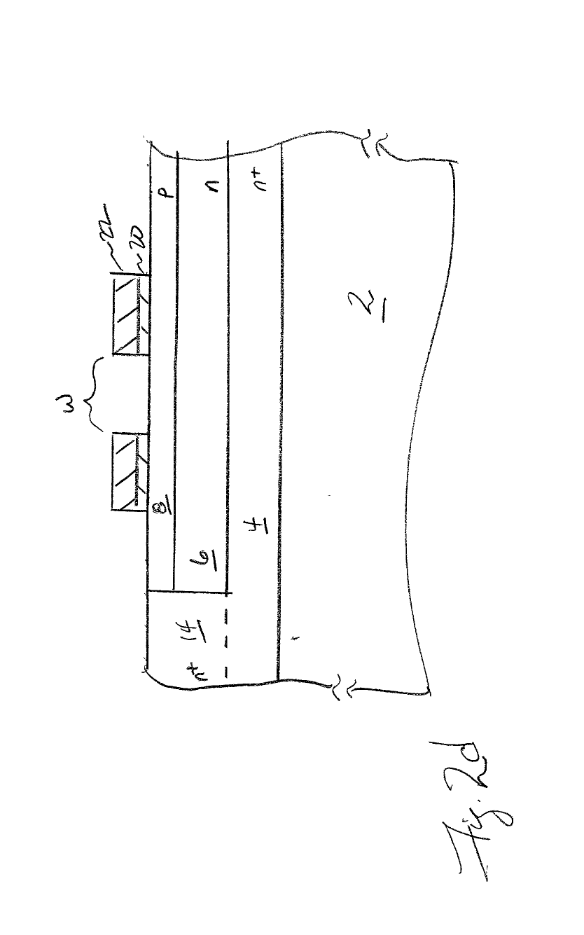

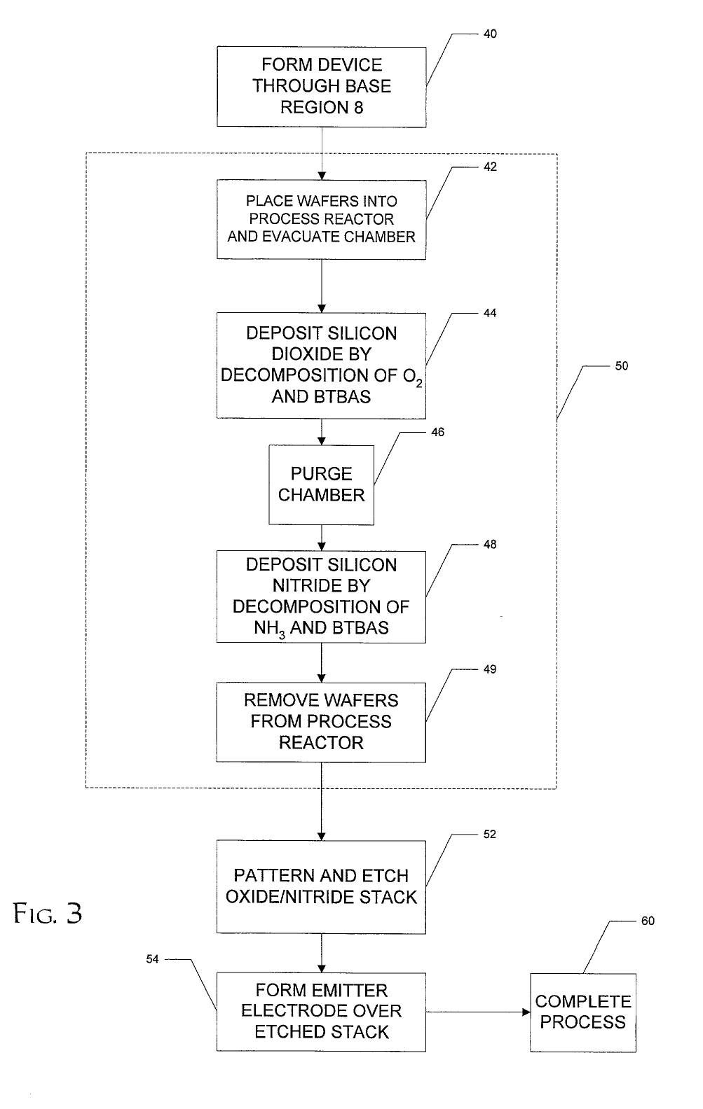

Referring now to FIGS. 2a through 2d in combination with FIG. 3, a method of fabricating a bipolar transistor according to the preferred embodiment of the invention will now be described. The same reference numerals will be used for similar elements as described above relative to FIGS. 1a and 1b. As will be apparent from the following description, this exemplary transistor is of the double-diffused n-p-n type. It is contemplated, however, that those skilled in the art having reference to this specification will be readily able to apply the inventive features of the present invention to other devices and implementations. It is further contemplated that such alternative realizations of the present invention are within the scope of the present invention as claimed below.

The process begins, according to this embodiment of the invention, with the fabrication of the bipolar transistor to form its collector and base elements. In the flow of FIG. 3, this conventional processing is referred to as process 40. According to the preferred embodiment of the invention, process 40 is performed according to conventional method steps to form these elements, resulting in a structure as illustrated in FIG. 2a. As shown in FIG. 2a, the transistor structure includes buried n+ collector region 4 at a surface of substrate 2. Lightly-doped n-type intrinsic collector region 6 is formed over buried n+ collector region 4, for example by way of conventional epitaxy with in situ n-type doping or followed by ion implantation. Further epitaxial silicon growth is then performed to form intrinsic p-type base layer 8 with the desired base region doping concentration and distribution, at the surface of collector region 6 as shown in FIG. 2a. Also as shown in FIG. 2a, collector sinker structure 14 is formed in the conventional manner, for example by way of a masked ion implant, to provide a low resistance contact from the surface of the structure to buried collector layer 4.

According to the preferred embodiment of the invention, as shown in FIG. 3, process 50 is next performed to form an emitter dielectric layer over base region 8. This emitter dielectric layer, according to this embodiment, is formed of a stacked dielectric layer that includes silicon dioxide (SiO₂) and silicon nitride (Si₃N₄). Process 50 corresponds to a single vacuum step, in that wafers on which the transistor structure of FIG. 2a have been formed are exposed to a sequence of process operations within a process chamber to form the stack emitter dielectric layer, without removing the wafers from the chamber. The particular operations within process 50 according to the preferred embodiment of the invention will now be described in further detail.

In process 42, the wafers are placed into a low pressure chemical vapor deposition (LPCVD) process chamber or reactor. According to the preferred embodiment of the invention, the process chamber is a vertical CVD furnace suitable for use with liquid precursors, and as such includes the appropriate liquid bubbler. Preferably, the process chamber is of the vertical type, able to receive many wafers for simultaneous CVD processing. A preferred example of a vertical LPCVD furnace suitable for use in process 50 is the TEL α-8 vertical oxidation/diffusion LP-CVD system available from Tokyo Electron Ltd., which can receive up to 150 wafers. Following such loading, the system is evacuated to a low pressure. According to the preferred embodiment of the invention, using the TEL α-8 system by way of example, the pressure in the process chamber is pumped down to on the order of 300 to 500 mTorr, at a temperature of about 550° to 650° C. A stabilization period of on the order of twenty minutes then elapses.

Once the chamber is loaded and evacuated in process 42, CVD process 44 is then performed to deposit silicon dioxide 20 over the surface, resulting in a structure as shown in FIG. 2b. According to the preferred embodiment of the invention, the CVD of silicon dioxide is performed by a liquid precursor of bistertiarybutylaminosilane (BTBAS) to produce a corresponding vapor of BTBAS, while introducing a flow of oxygen. The ratio of oxygen to BTBAS preferably ranges from about 2:1 to 6:1, with a preferred ratio being about 4:1. CVD process 44 is preferably performed at about 600° C. and at a pressure of about 300 to 400 mTorr. The oxygen reacts with the BTBAS vapor, resulting in the deposition of silicon dioxide 20 overall, as shown in FIG. 2b. Silicon dioxide 20 is deposited, in this example at a rate of 60 to 70 Å/minute or greater, until the desired thickness of silicon dioxide 20 is formed.

Upon depositing silicon dioxide 20 to the desired thickness, for example on the order of 1150 Å, process 44 is complete. In process 46, the chamber is evacuated of the gases used to deposit silicon dioxide; it is contemplated that such a purge cycle may be performed in about 10 minutes. The wafers are not removed from the reactor for this purge of process 46, and the temperature and pressure remain about the same as during the CVD of process 44. The wafers thus remain at a temperature of about 600° C., at relatively low pressure.

Process 48 is then carried out to deposit silicon nitride on the wafers in the process chamber. According to the preferred embodiment of the invention, CVD process 44 is performed by again bubbling the liquid precursor of bistertiarybutylaminosilane (BTBAS) to produce a corresponding vapor of BTBAS, while introducing a flow of ammonia (NH₃). Preferably, these gases are in a ratio of from about 2:1 to 3:1 (NH₃ to BTBAS), with deposition carried out at a pressure of about 300 to 400 mTorr at a temperature of around 600° C., resulting in a deposition rate of about 20 Å/minute or greater. The process continues until the desired thickness of silicon nitride film 22 is formed, for example to a thickness of on the order of 350 Å. The resulting structure, including deposited silicon nitride film 22, is illustrated in FIG. 2c.

Upon completion of the CVD of the desired thickness of silicon nitride 22, the CVD process chamber is purged and backfilled in the conventional manner. Following the appropriate stabilization period, such as on the order of forty minutes, the process chamber is then unloaded in the conventional manner, in process 49 of FIG. 3.

The transistor structure including a emitter dielectric stack of silicon dioxide 20 and silicon nitride 22, as shown in FIG. 2c, is then processed to complete the fabrication of the desired transistor devices in the integrated circuit. First, the emitter dielectric of silicon dioxide 20 and silicon nitride 22 is photolithographically patterned and etched, in process 52, to define its location overlying base region 8. The etch may be carried out by way of a sequence of etches applied to silicon nitride 22 and then silicon dioxide 20, preferably by way of a dry plasma etch. FIG. 2d illustrates the result of process 52, in which the emitter dielectric of silicon dioxide 20 and silicon nitride 22 is formed over base region 8, with window opening W formed therethrough.

A polysilicon layer is then deposited over the emitter dielectric of silicon dioxide 20 and silicon nitride 22, and patterned to define the emitter polysilicon electrode, in process 54. The polysilicon layer is n-type doped in situ with its deposition, or alternatively is implanted with dopant, in the desired manner. Following deposition and patterning of the emitter polysilicon, in this embodiment the wafer is heated to diffuse n-type dopant from the emitter polysilicon into base region 8 through window location W in the emitter dielectric of silicon dioxide 20 and silicon nitride 22.

The remainder of the integrated circuit fabrication process according to the preferred embodiment of the invention is then carried out. This processing, shown in FIG. 3 as process 60, includes the formation of overlying insulator layers, metallization and other interconnect layers, and the like, as appropriate for the technology used. Following the fabrication of all levels specified by the design of the overall integrated circuit, wafer fabrication will generally be completed by the application of a protective overcoat, through which openings to metal bond pads or other connective lands are made. Following wafer fabrication and any desired electrical testing of the integrated circuits in wafer form, such “back-end” processes as dicing of the individual circuits from the wafer, electrical test, packaging, burn-in, and additional electrical testing, are then typically performed to result in a packaged integrated circuit that may then be implemented into end equipment; it is understood that such additional wafer fabrication and back-end processes shall not constitute a material change in the integrated circuit structure described herein.

Other alternative implementations of the present invention are also contemplated. For example, the present invention may be used to deposit a stack film of silicon nitride underlying silicon dioxide in a single vacuum step, either for use as an emitter dielectric or in other applications. In another implementation, a single vacuum step for the LPCVD from BTBAS may be used to deposit a layer of silicon dioxide followed by a layer of silicon nitride, to define the “moat” or active regions at which field oxide is not to be formed by way of a subsequent local oxidation of silicon (LOCOS) process. In this LOCOS alternative, it is contemplated that the silicon dioxide underlying the silicon nitride would provide an extremely smooth interface at the silicon surface. It is contemplated that this and other alternative implementations of the present invention will be apparent to those skilled in the art having reference to this specification.

The present invention provides important advantages in the fabrication of integrated circuits, particularly those having extremely shallow junction depths and sensitivity to doping concentration and distribution. As evident from the foregoing description, the deposition of both silicon nitride and silicon oxide may be carried out at low temperatures and short process times. For example, the stack deposition may be performed, according to the present invention, at a temperature that is below the boron activation temperature of 700° C., enabling the deposition of these important insulator films to be carried out without substantially affecting the critical dopant distribution in the base region of an n-p-n bipolar transistor. This low temperature deposition also has a minimal effect on the thermal budget of the process considering that both films may be deposited in a single vacuum cycle, and therefore requiring less time at temperature. For example, it is contemplated that the deposition of both the silicon nitride and silicon dioxide films may be carried out in as few as 4.5 hours per batch, in contrast to the 8.5 hours required for conventional two-step CVD of these films. Furthermore, the single vacuum process reduces the equipment required for the process.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as subsequently claimed herein.

We claim:

1. A method of forming a stack insulator layer in the fabrication of an integrated circuit structure at a surface of a semiconductor wafer, comprising the steps of:
placing the wafer into a process chamber;
reacting bistertiarybutylaminosilane with a nitrogen-bearing gas in the chamber to deposit silicon nitride on the wafer;
reacting bistertiarybutylaminosilane with an oxygen-bearing gas in the chamber to deposit silicon dioxide on the wafer; and
after the reacting steps, then removing the wafer from the process chamber.

2. The method of claim 1, further comprising:
after the placing step, and before the reacting steps, evacuating the process chamber to a pressure at or below about 500 mtorr.

3. The method of claim 2, further comprising:
after the placing step, maintaining a temperature in the process chamber below about 650° C.

4. The method of claim 1, further comprising:
after the placing step, maintaining a temperature in the process chamber below about 650° C.

5. The method of claim 1, wherein the step of reacting bistertiarybutylaminosilane with a nitrogen-bearing gas is performed before the step of reacting bistertiarybutylaminosilane with a n oxygen-bearing gas.

6. The method of claim 1, wherein the step of reacting bistertiarybutylaminosilane with an oxygen-bearing gas is performed before the step of reacting bistertiarybutylaminosilane with a nitrogen-bearing gas.

7. The method of claim 1, wherein the nitrogen-bearing gas is ammonia.

8. The method of claim 1, wherein the oxygen-bearing gas is oxygen.

9. The method of claim 1, further comprising:
after the placing step, bubbling bistertiarybutylaminosilane liquid to produce a vapor of bistertiarybutylaminosilane.

10. A method of fabricating a bipolar transistor at a semiconductor surface of a substrate, comprising:
forming a collector layer at the surface;
forming a base layer overlying the collector layer;
then placing the wafer into a process chamber;
reacting bistertiarybutylaminosilane with a nitrogen-bearing gas in the chamber to deposit silicon nitride on the base layer;
reacting bistertiarybutylaminosilane with an oxygen-bearing gas in the chamber to deposit silicon dioxide on the silicon nitride;
after the reacting steps, then removing the wafer from the process chamber;
etching a window opening through the silicon dioxide and silicon nitride to expose a portion of the base layer; and
then forming an emitter electrode over the silicon dioxide and into the window opening to contact the base layer.

11. The method of claim 10, further comprising:
after the placing step, and before the reacting steps, evacuating the process chamber to a pressure at or below about 500 mTorr.

12. The method of claim 11, further comprising:
after the placing step, maintaining a temperature in the process chamber below about 650° C.

13. The method of claim 10, further comprising:
after the placing step, maintaining a temperature in the process chamber below about 650° C.

14. The method of claim 10, wherein the nitrogen-bearing gas is ammonia.

15. The method of claim 10, wherein the oxygen-bearing gas is oxygen.

16. The method of claim 10, further comprising:
after the placing step, bubbling bistertiarybutylaminosilane liquid to produce a vapor of bistertiarybutylaminosilane.
